(19) United States
(12) Patent Application Publication
(10) Pub. No.: US 2004/0203231 A1
(43) Pub. Date: Oct. 14, 2004

(54) Method for forming a semiconductor device with a contact plug

(76) Inventor: Jung-Yuan Hsieh, Hsinchu (TW)

Correspondence Address: KNOBBE MARTENS OLSON & BEAR LLP, 2040 MAIN STREET, FOURTEENTH FLOOR, IRVINE, CA, 92614, US

(21) Appl. No.: 10/413,596

(22) Filed: Apr. 14, 2003

(51) Int. Cl. H01L 21/3205; H01L 21/4763; H01L 21/44

(52) U.S. Cl. 438/669; 438/672; 438/643; 438/648

(57) ABSTRACT

A method for forming a contact plug is described. First, two gates are formed on a semiconductor substrate. Thereafter, a first dielectric layer is deposited on the semiconductor substrate, and then etched back to form a spacer on sidewalls of the gates. An ion implantation is performed to form a source and a drain region in the semiconductor substrate. Then, a conductive layer is deposited on the semiconductor substrate and the transistor. A portion of the conductive layer is removed to while leaving a retained conductive layer disposed over the source region and the drain region. Finally, a second dielectric layer is deposited on the semiconductor substrate, the transistor and the retained conductive layer.

### BACKGROUND OF THE INVENTION

1. Field of Invention

The present invention relates to a method for forming a contact plug. More particularly, the present invention relates to a method for forming a contact plug in a fabrication process of a semiconductor product.

2. Description of Related Art

The trend in semiconductor products manufacture is towards a reduced line-width. Decreasing the area of the source/drain region in contact with the conductive lines, i.e. the size of the contact window, is one way to increase the integration of a metal-oxide-semiconductor field effect transistor (MOSFET). However, due to small diameter of the contact window, a photolithography process for forming the contact window risks misalignment. A novel self-aligned contact (SAC) process has emerged to solve this problem. Consequently, the line-width of the semiconductor products can be reduced without threat of misalignment.

Reference is made to FIGS. 1A-1G, which are schematic, cross-sectional views illustrating a SAC process in accordance with the prior art. As shown in FIG. 1A, a gate oxide layer 13 and a gate 111 are formed first on the surface of a semiconductor substrate 10. The gate 111 includes a masking layer 1111, e.g. a silicon nitride layer or a silicon oxide layer, and a polysilicon layer 1112. A silicon nitride layer 12 is then deposited on the semiconductor substrate 10 and the gate 111.

In FIG. 1B, the silicon nitride layer 12 is etched back to stop on the gate oxide layer 13 so that a spacer 14 is formed on the sidewalls of gate 111. According to the conventional art, the silicon nitride layer 12 could be etched back to alternatively stop on the semiconductor substrate 10. FIG. 1B is shown for one of the embodiments to explain the technique of the conventional art.

In FIG. 1C, an ion implantation step 15 is performed with the gate 111 and the spacer 14 serving as a mask to form a source/drain region 112 in the semiconductor substrate 10.

In FIG. 1D, a silicon nitride layer 16, which serves as an etching stop layer, and a dielectric layer 171 are subsequently deposited on the gate oxide layer 13, the gate 111 and the spacer 14. Thereafter, a portion of the dielectric layer 171 is removed by performing photolithography and etching, and another portion of the dielectric layer 171 disposed over the gate 111 is retained such that a contact window 18 is formed.

In FIG. 1E, an etching step is performed to remove the silicon nitride layer 16 and the gate oxide layer 13 at the bottom of the contact window 18.

In FIG. 1F, after depositing a polysilicon layer on the dielectric layer 171 and in the contact window 18, the polysilicon layer is etched back to retain the polysilicon layer 19 in the contact window 18.

Finally, as shown in FIG. 1G, another dielectric layer 172 is deposited on the dielectric layer 171 and the retained polysilicon layer 19 to accomplish manufacture of the contact window.

Although the misalignment problem is solved, another problem arises with further integration of MOSFET. When the integration of MOSFET further increases, the distance between two adjacent gates 111 further decreases, to possibly less than about 0.15 micrometer, and the silicon nitride layer 16 existing alongside the spacer 14 further truncates the distance therebetween. Therefore, in FIG. 1D, an etching technique performed to remove a portion of the dielectric layer 171 for forming the contact window 18 cannot completely remove the dielectric layer 171 at the bottom of the contact window 18. Finally, a residue 173 is left at the bottom of the contact window 18 after etching (as shown in FIG. 2). Even if the etching time is extended, the polymer deposited on the interior surface of the contact window 18 during etching process, and particularly at the bottom of the contact window 18, still cannot be completely removed. The residue increases the contact resistance between the source/drain region 112 and the conductive lines, and the performance of MOSFET is lowered.

### SUMMARY OF THE INVENTION

For the forgoing reasons, there is a need to develop a novel method for forming a contact plug to solve above problems. It is therefore an objective of the present invention to provide a method for forming a contact plug that completely removes the dielectric layer at the bottom of the contact window for improving the contact resistance.

In accordance with the foregoing and other objectives of the present invention, a method for forming a contact plug is described. First, two gates are formed on a semiconductor substrate. Thereafter, a first dielectric layer is deposited on the semiconductor substrate, and then etched back to form a spacer on sidewalls of the gates. An ion implantation is performed to form a source and a drain region in the semiconductor substrate. Then, a conductive layer is deposited on the semiconductor substrate and the transistor. A portion of the conductive layer is removed to while leaving a retained conductive layer disposed over the source region and the drain region. Finally, a second dielectric layer is deposited on the semiconductor substrate, the transistor and the retained conductive layer.

The deposited conductive layer can be a polysilicon layer or a tungsten layer. If the deposited conductive layer is a tungsten layer, a step of depositing a barrier layer is further included before depositing the tungsten layer, and a step of removing a portion of barrier layer exposed by the retained conductive layer is further included after removing the portion of the conductive layer.

It is to be understood that both the foregoing general description and the following detailed description are examples only, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A-1G are schematic, cross-sectional views illustrating a SAC process in accordance with the prior art;

FIG. 2 is a schematic, cross-sectional view showing a residue remaining at the bottom of a contact window during a SAC process in accordance with the prior art;

FIGS. 3A-3F are schematic, cross-sectional views illustrating a process of forming a contact plug according to one preferred embodiment of the present invention; and

FIGS. 4A-4C are schematic, cross-sectional views illustrating a process of forming a contact plug according to another preferred embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

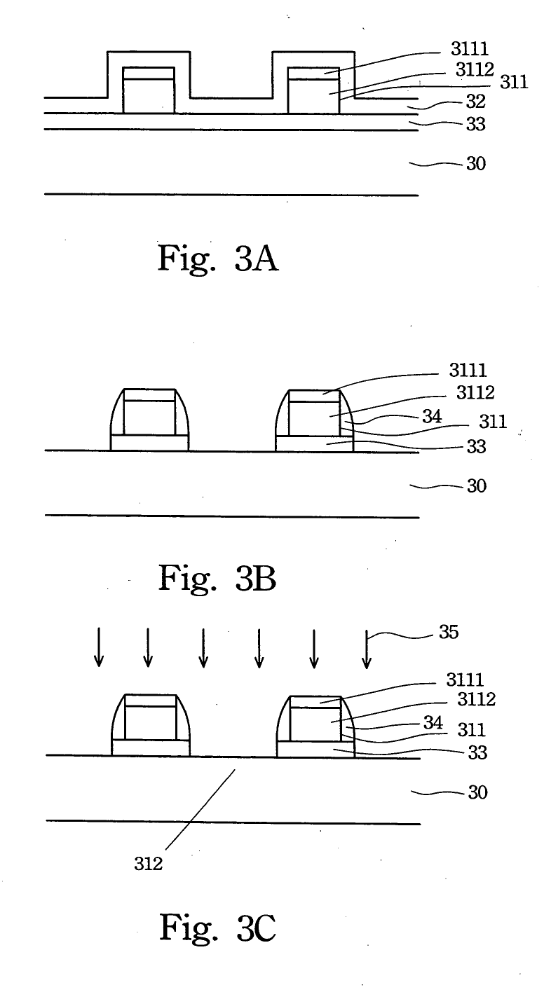

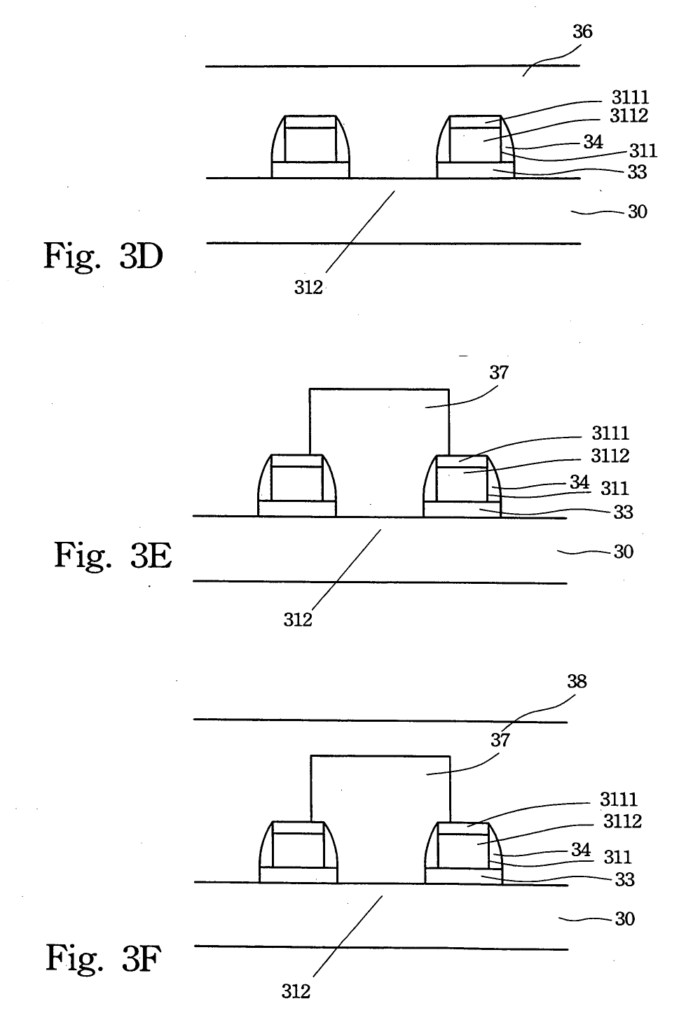

Reference is made to FIGS. 3A-3F, which are schematic, cross-sectional views illustrating a process of forming a contact plug according to one preferred embodiment of the present invention. As shown in FIG. 3A, a gate oxide layer 33 and plural gates 311 are first formed on the surface of a semiconductor substrate 30. The gate 311 includes a masking layer 3111, e.g. a silicon nitride layer or a silicon oxide layer which can be deposited by low pressure chemical vapor deposition (LPCVD), and a polysilicon layer 3112. The semiconductor substrate 30 is preferably a silicon substrate. Then, an ion-implantation shielding layer 32 is deposited on the semiconductor substrate 30 and the gate 311. The ion-implantation shielding layer 32 is preferably made of silicon nitride or silicon oxide.

In FIG. 3B, the ion-implantation shielding layer 32 is etched back to stop on the semiconductor substrate 30 so that a spacer 34 is formed on sidewalls of the gate 311.

In FIG. 3C, an ion implantation step 35 is performed with the gate 311 and the spacer 34 serving as mask to form a source/drain region 312 in the semiconductor substrate 30. The gate 311 on the semiconductor substrate 30 and the source/drain region 312 in the semiconductor substrate 30 together comprises a transistor.

In FIG. 3D, a conductive layer 36 is deposited on the semiconductor substrate 30, the gate 311 and the spacer 34. The conductive layer 36 is preferably a polysilicon layer, and the polysilicon layer is deposited by chemical vapor deposition.

In FIG. 3E, one portion of the conductive layer 36 is removed while retaining another portion of the conductive layer 36 disposed over the source/drain region 312 so that a contact plug 37 is formed. The intended removed conductive layer 36 is preferably first defined by photolithography, and then removed by etching.

Finally, as shown in FIG. 3F, a dielectric layer 38 is deposited on the semiconductor substrate 30, the gate 311, the spacer 34, and the contact plug 37 to accomplish manufacture of the contact window. The dielectric layer 38 is preferably made of Borophosphosilicate Glass (BPSG) deposited by chemical vapor deposition.

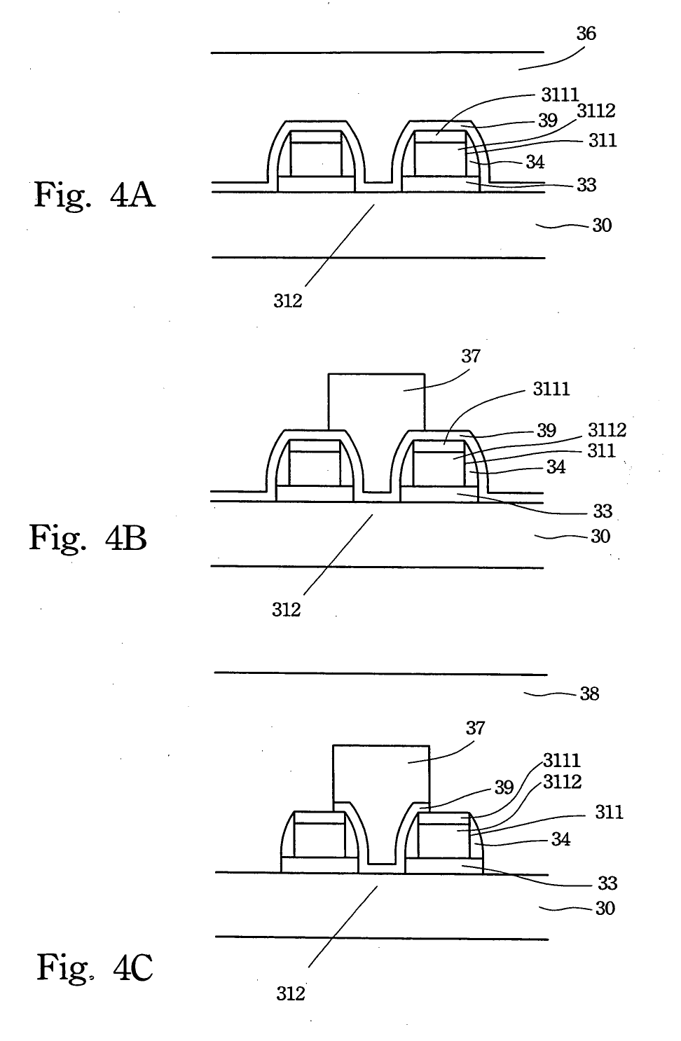

Reference is made to FIGS. 4A-4C, which are schematic, cross-sectional views illustrating a process of forming a contact plug according to another preferred embodiment of the present invention. According to the present invention, the conductive layer 37 can be a tungsten layer as well as a polysilicon layer. If the deposited conductive layer is a tungsten layer, in FIG. 3D, a step of depositing a barrier layer 39 is further included before depositing the tungsten layer 36. That is, a barrier layer 39 and a tungsten layer 36 are subsequently deposited on the semiconductor substrate 30 and the gate 311 and the spacer 34 (as shown in FIG. 4A). The barrier layer 39 is preferably made of titanium nitride deposited by chemical vapor deposition or sputtering. Then, as shown in FIG. 4B, one portion of the tungsten layer 36 is removed while retaining another portion of the tungsten layer 36 disposed over the source/drain region 312 so that a contact plug 37 is formed. Similarly, the intended removed tungsten layer 36 can be first defined by photolithography, and then removed by etching. Finally, in FIG. 4C, a portion of barrier layer 39 exposed by the contact plug 37 is removed, and a dielectric layer 38 is deposited on the semiconductor substrate 30, the gate 311, the spacer 34, and the contact plug 37 to accomplish manufacture of the contact window. Similarly, the dielectric layer 38 can be made of Borophosphosilicate Glass (BPSG) deposited by chemical vapor deposition.

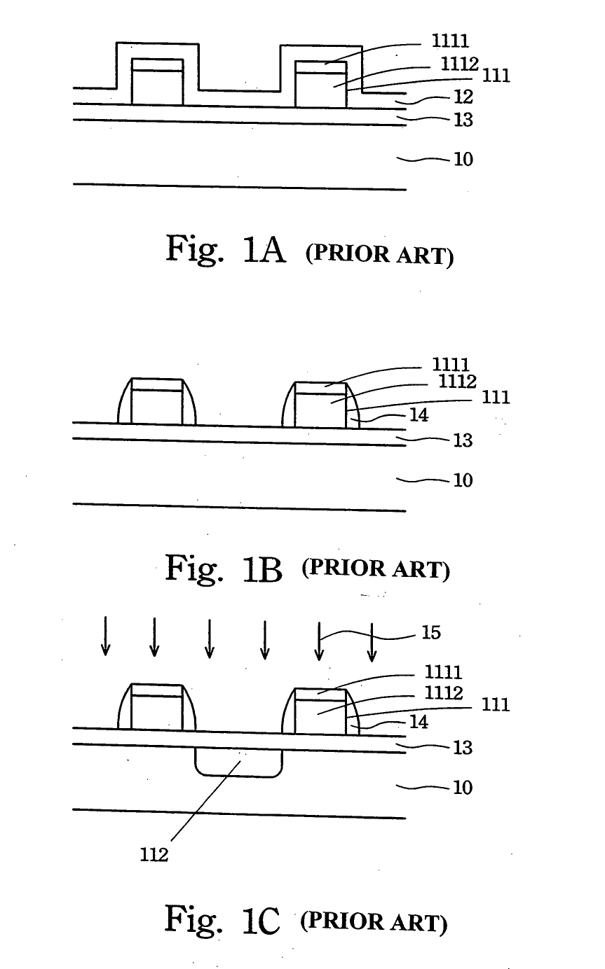

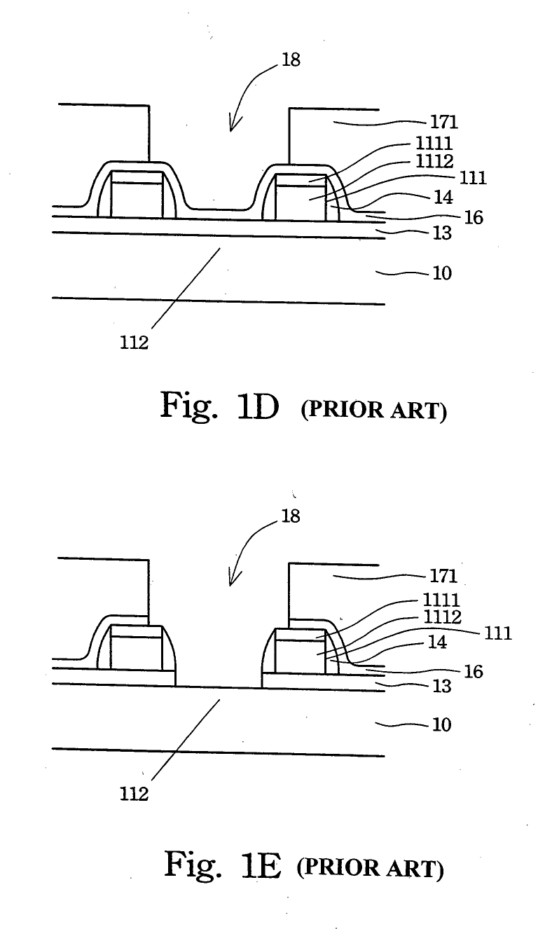

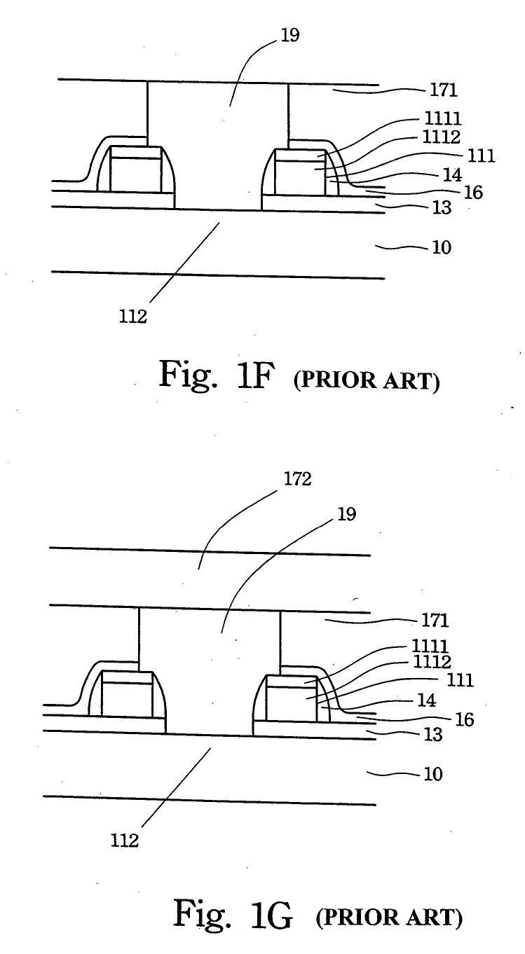

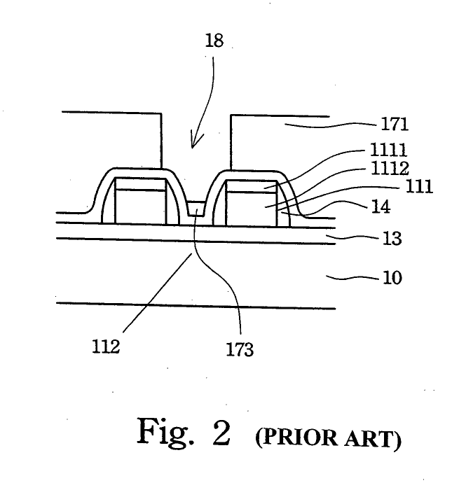

According to the prior art (FIG. 1D), a portion of the dielectric layer 171 is removed to form the contact window 18, and the polysilicon layer 19 is deposited thereafter. Therefore, when the distance between two adjacent gates 111 further decreases, more likely less than 0.15 micrometer, the dielectric layer 171 at the bottom of the contact window 18 cannot be completely removed during etching. Finally, a residue 173 is left at the bottom of the contact window 18 after performing etching technique (FIG. 2). In contrast, according to the present invention (FIGS. 3E-3F), the conductive layer 36 is deposited first. Then, a portion of the conductive layer 36 is removed to form the contact plug 37, and the dielectric layer 38 is deposited thereafter. Accordingly, even though the distance between two adjacent gates further decreases to possibly less than about 0.15 micrometer, there is no problem of residue left at the bottom of the contact window.

In addition, compared with the prior art, the method for forming the contact plug according to the present invention is significantly simplified. The present invention does not need to deposit a silicon nitride layer 16 as illustrated in FIG. 1D, and therefore the present invention does not have to include a step of removing the silicon nitride layer 16 at the bottom of the contact window 18 as illustrated in FIG. 1E. The present invention also does not includes the steps of first defining the intended removed partial dielectric layer 171 by photolithography, and then removing it by etching to form the contact widow 18, as illustrated in FIG. 1F.

Further, according to the prior art (FIG. 1B), the silicon nitride layer 12 is etched back to stop on the gate oxide layer 13. Due to the thinness of the gate oxide layer 13, the end point is difficult to control in the prior art. In contrast, according to the present invention (FIG. 3B), the ion-implantation shielding layer 32 is etched back to stop on the semiconductor substrate 30. The present invention easily controls the end point.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A method of forming a semiconductive device with a contact plug, said method comprising the steps of:
forming two gates on a semiconductor substrate;
depositing a first dielectric layer on said semiconductor substrate;
etching back said first dielectric layer to form a spacer on sidewalls of said gates;
performing ion implantation to form a source and drain region in said semiconductor substrate;
directly depositing a conductive layer on said semiconductor substrate, said source and drain regions and said gates such that said conductive layer globally covers all of said gates and said substrate positioned between said gates;
removing a portion of said conductive layer positioned at least over said gates so as to expose said gates while leaving retained conductive layer disposed over said source region and said drain region to form the contact plug; and
depositing a second dielectric layer on said semiconductor substrate said gates and retained conductive layer after removal of said portion of said semiconductor layer so as to expose said gates.

2. The method according to claim 1, wherein said gate comprises a masking layer, a polysilicon layer and a gate oxide layer.

3. The method according to claim 2, wherein said masking layer is a silicon nitride layer.

4. The method according to claim 2, wherein said masking layer is a silicon oxide layer.

5. The method according to claim 1, wherein said semiconductor substrate is a silicon substrate.

6. The method according to claim 1, wherein said conductive layer is a polysilicon layer.

7. The method according to claim 6, wherein said polysilicon layer is deposited by chemical vapor deposition.

8. The method according to claim 1, wherein said conductive layer is a tungsten layer.

9. The method according to claim 8, wherein said tungsten layer is deposited by chemical vapor deposition.

10. The method according to claim 9, wherein said method further comprises depositing a barrier layer before depositing said tungsten layer.

11. The method according to claim 10, wherein said barrier layer is made of titanium nitride.

12. The method according to claim 10, wherein said method further comprises removing said barrier layer exposed by said retained conductive layer after removing said portion of said conductive layer.

13. The method according to claim 1, wherein said first dielectric layer is made of a material selected from a group consisting of silicon nitride and silicon oxide.

14. The method according to claim 13, wherein said first dielectric layer is deposited by low pressure chemical vapor deposition.

15. The method according to claim 1, wherein said second dielectric layer is made of Borophosphosilicate Glass (BPSG).

16. The method according to claim 1, wherein said second dielectric layer is deposited by chemical vapor deposition.

17. The method according to claim 1, wherein said portion of said conductive layer is first defined by photolithography, and then removed by etching.
